(19) United States
(12) Patent Application Publication
(10) Pub. No.: US 2018/0286955 A1
(43) Pub. Date: Oct. 4, 2018

(54) SEMICONDUCTOR DEVICE

(71) Applicant: KABUSHIKI KAISHA TOSHIBA, Tokyo (JP)

(72) Inventor: Keiko KAWAMURA, Yokkaichi Mie (JP)

(21) Appl. No.: 15/690,248

(22) Filed: Aug. 29, 2017

(30) Foreign Application Priority Data
Mar. 30, 2017 (JP) 2017-067313

(51) Int. Cl. H01L 29/417; H01L 29/739

(52) U.S. Cl. CPC H01L 29/41708; H01L 29/7397

(57) ABSTRACT

A semiconductor device includes first and second electrodes, a first semiconductor region between the first and second electrodes, a second semiconductor region between the first semiconductor region and the second electrode, a third semiconductor region between the second semiconductor region and the second electrode, a fourth semiconductor region between the third semiconductor region and the second electrode, a fifth semiconductor region between first and second portions of the fourth semiconductor region, first and second conductive regions extending inwardly of second, third and fourth semiconductor regions and insulated therefrom, an insulating region between the fourth semiconductor region and the second electrode and between the first and second conductive regions and the second electrode, and third and fourth conductive regions extending from respective first and second conductive regions inwardly of the third insulating region. Widths of third and fourth conductive regions are less than widths of first and second conductive regions, respectively.

This application is based upon and claims the benefit of priority from Japanese Patent Application No. 2017-067313, filed Mar. 30, 2017, the entire contents of which are incorporated herein by reference.

### FIELD

Embodiments described herein relate generally to a semiconductor device.

### BACKGROUND

As power semiconductor devices for electric power control, an IGBT (Insulated Gate Bipolar Transistor), an IEGT (Injection Enhanced Gate Transistor), a MOSFET (metal-oxide-semiconductor field-effect transistor), and the like are used. In the case of a device having a large chip size, where gate resistance is high, an ON/OFF delay occurs within the device at a time of switching, which often results in breakdown. Furthermore, switching loss is increased.

### DESCRIPTION OF THE DRAWINGS

FIG. 1 is a plan view illustrating lead interconnection portions of a semiconductor device according to a first embodiment.

FIG. 2 is a schematic cross-sectional view taken along A-A′ of FIG. 1.

FIG. 3 is a schematic cross-sectional view of a semiconductor device according to a comparative example to correspond to FIG. 2.

FIG. 4 is a schematic cross-sectional view of a semiconductor device according to a second embodiment to correspond to FIG. 2.

FIG. 5 is a schematic cross-sectional view of a semiconductor device according to a third embodiment to correspond to FIG. 2.

FIG. 6 is a schematic cross-sectional view of a semiconductor device according to a fourth embodiment to correspond to FIG. 2.

### DETAILED DESCRIPTION

Embodiments provide a semiconductor device capable of reducing a gate resistance.

In general, according to one embodiment, a semiconductor device includes first and second electrodes, a first semiconductor region of a first conductivity type between the first electrode and the second electrode, a second semiconductor region of a second conductivity type between the first semiconductor region and the second electrode, a third semiconductor region of the first conductivity type between the second semiconductor region and the second electrode, a fourth semiconductor region of the second conductivity type between the third semiconductor region and the second electrode and having first and second portions, a fifth semiconductor region of the first conductivity type between the first and second portions of the fourth semiconductor region, a first conductive region extending inwardly of the second, third and fourth semiconductor regions and spaced therefrom by a first insulating region, a second conductive region extending inwardly of the second, third and fourth semiconductor regions and spaced therefrom by a second insulating region, the first and second conductive regions extending in a first direction within the third, fourth, and fifth semiconductor regions and spaced from each other in a second direction orthogonal to the first direction, a third insulating region between the fourth semiconductor region and the second electrode and between the first and second conductive regions and the second electrode, a third conductive region extending from the first conductive region inwardly of the third insulating region, and a fourth conductive region extending from the second conductive region inwardly of the third insulating region, the third and fourth conductive regions extending in the first direction and spaced from each other in the second direction. The widths of the third and fourth conductive regions in the second direction are less than the widths of the first and second conductive regions in the second direction, respectively.

Embodiments will be described hereinafter with reference to the drawings. In the description below, the same constituent elements are denoted by the same reference numbers and symbols throughout the Figs., and the description of a constituent element already discussed, is omitted as appropriate when discussing a later Fig.

It is noted that the relationship between the thickness and the width of each element, the relative proportions of elements and the like in the drawings are not necessarily identical to those of an actual device. Furthermore, the same elements may be illustrated with different sizes or different proportions depending on the drawing Fig.

### First Embodiment

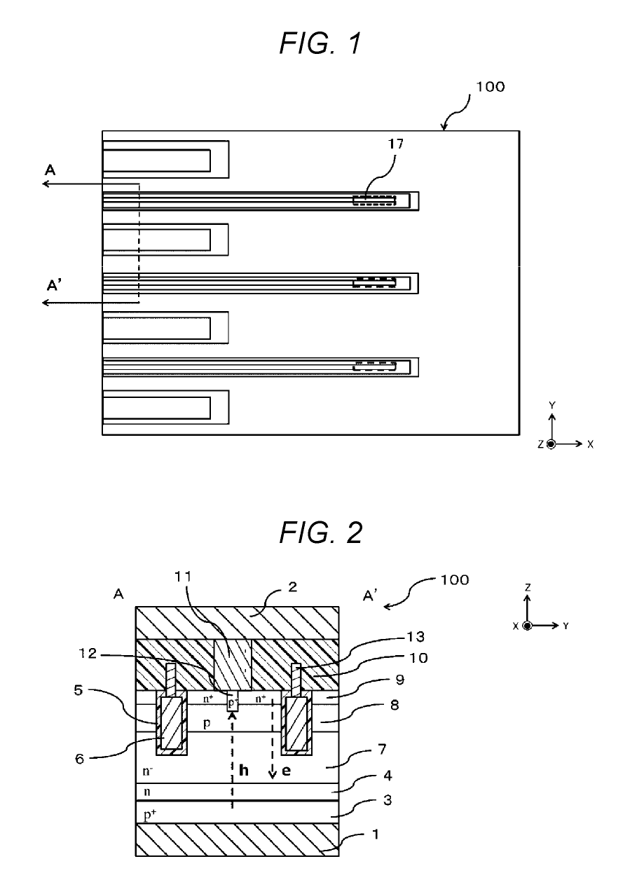

A first embodiment of the present disclosure will be described with reference to FIGS. 1 and 2. FIG. 1 is a plan view illustrating lead interconnection portions 17 of a semiconductor device 100 according to the first embodiment. In the present specification, the semiconductor devices according to the embodiments of the present disclosure are described as having an IGBT structure; however, the IGBT structure is presented by way of example only and semiconductor devices having an IEGT or MOSFET structure are similarly applicable. Moreover, when the semiconductor device is a MOSFET, the second electrode is not an emitter electrode but is a source electrode.

In the drawings, a three-dimensional coordinate system (XYZ coordinate system) is used to represent directions on or in the semiconductor device. An X direction and a Y direction are orthogonal to each other in the same plane. A Z direction is orthogonal to the X direction and the Y direction. FIG. 2 is a schematic cross-sectional view taken along A-A′ of FIG. 1.

A configuration of the semiconductor device 100 according to the first embodiment will first be described. As shown in FIG. 2, the semiconductor device 100 includes a collector electrode 1, an emitter electrode 2, a p⁺ collector region 3, an n drift region 4, gate oxide films 5, gate electrodes 6, an n drift region 7, a p base region 8, an n⁺ emitter region 9, an oxide film 10, a contact plug 11, a p⁺ contact region 12, and gate plugs 13. It is noted that the n drift region 4 and the n⁻ drift region 7 can be regarded as one semiconductor region.

The semiconductor device 100 according to the first embodiment has an upper-lower electrode structure. The semiconductor device 100 includes the collector electrode 1 and the emitter electrode 2. The direction from the collector electrode 1 to the emitter electrode 2 is the Z direction.

In the semiconductor device 100, the p⁺ collector region 3 is located between the collector electrode 1 and the emitter electrode 2, and the p⁺ collector region 3 is electrically connected to the collector electrode 1. The n drift region 4 is located between the emitter electrode 2 and the p⁺ collector region 3.

In the Z direction, the n⁻ drift region 7, the p base region 8, and the n⁺ emitter region 9 are located in this order from the n drift region 4 between the n drift region 4 and the emitter electrode 2.

The n⁺ emitter region 9 is provided between the p base region 8 and the emitter electrode 2. The p⁺ contact region 12 is provided within the p base region 8 and the n⁺ emitter region 9.

Furthermore, the gate electrodes 6 extend into the n⁻ drift region 7, through the p base region 8, and into the n⁺ emitter region 9, with the gate insulating film 5 therebetween. The gate electrodes 6 extend in the X direction and the Z direction. A plurality of the gate electrodes 6 are spaced from one another in the Y direction.

An oxide film 10 is located between a part of the n⁺ emitter region 9 and the emitter electrode 2.

A gate plug 13 is located on each of the gate electrodes 6 and extends therefrom in the Z direction through the gate insulating film and inwardly of the oxide film 10. The gate plug 13 electrically connects to each of the gate electrodes 6.

The contact plug 11 is provided on a part of the n⁺ emitter region 9 and on the p⁺ contact region 12. One end of the contact plug 11 in the Z direction is electrically connected to the n⁺ emitter region 9 and the p⁺ contact region 12 whereas the other end of the contact plug 11 is electrically connected to the emitter electrode 2. That is, the contact plug 11 is located between the emitter electrode 2 and both the n⁺ emitter region 9 and the p⁺ contact region 12.

Furthermore, a gate interconnection for connection to of the gate plug 13 to an external electrode extends from each lead interconnection portion 17 shown in FIG. 1.

An example of a material of each constituent element will now be described.

A main component of each of the plurality of semiconductor regions provided between the collector electrode 1 and the emitter electrode 2 is, for example, silicon (Si). Alternatively, the main component of each of the plurality of semiconductor regions may be silicon carbide (SiC), gallium nitride (GaN) or the like. As an impurity element of a conductivity type such as n⁺, n, and n⁻, phosphorus (P) or arsenic (A), for example, is doped into the silicon semiconductor regions. As an impurity element of the p⁺ and p conductivity type, for example boron (B), is used as the dopant. Moreover, the semiconductor device 100 exhibits similar effects even if the conductivity types of p and n are interchanged.

The material of the collector electrode 1 and the material of the emitter electrode 2 are, for example, a metal including at least one selected from a group consisting of aluminum (Al), titanium (Ti), nickel (Ni), tungsten (W), copper (Cu), gold (Au), and the like. The material of the gate electrodes 6 includes, for example, polysilicon. In addition, the material of the gate insulating films 5 includes, for example, silicon oxide or silicon nitride.

Furthermore, the material of the contact plug 11 and the gate plugs 13 includes tungsten (W).

The function and effect of the present embodiment will be described with reference to FIG. 2.

The function of the IGBT as the semiconductor device 100 according to the first embodiment will be described. FIG. 2 provides a simple illustration of the function of the IGBT together with its operation when the IGBT section is in an on state.

In the on state, a higher potential is applied to the collector electrode 1 than the potential applied to the emitter electrode 2, and a potential equal to or higher than a threshold potential (Vth) is supplied to the gate electrodes 6. In this case, an n channel region is formed on a surface of the p base region 8 along the gate insulating film 5, thereby turning on the IGBT section. Thus, an electron current (e) flows from the n⁺ emitter region 9 to the p base region 8, the n⁻ drift region 7, the n drift region 4, and the p⁺ collector region 3 in that order. Accordingly, a hole current (h) flows from the p⁺ collector region 3 to the n drift region 4, the n⁻ drift region 7, the p base region 8, the p⁺ contact region 12, and the contact plug 11 in that order.

The semiconductor device 100 is configured such that the gate plugs 13 and the contact plug 11 extend parallel to one another in the X direction, and the contact plug 11 is higher than the gate plugs 13 in the Z direction, i.e., above the n+ emitter region 9 and the p+ contact region 12 and the shortest distance therefrom to the collector electrode 1 is greater that the shortest distance of a gate electrode 6 to the collector electrode. It is thereby possible to secure a large area for the contact plug 11 without causing a short-circuit between the gate plugs 13 and the contact plug 11 in a multilayer wiring architecture.

Moreover, in the semiconductor device 100, it is possible to secure a large area for each gate electrode 6 by use of the gate plug 13. Furthermore, since each gate plug 13 is formed from metal, the overall circuit resistivity can be reduced and the gate resistance can be, therefore, reduced. Moreover, the gate plugs 13 and the contact plug 11 can be formed in a single process since the gate plugs 13 and the contact plug 11 are disposed parallel to one another in the X direction.

Furthermore, since the width of the gate plug 13 on each gate electrode 6 is smaller than the width of the gate electrode 6, the gate plug 13 is separated from the n⁺ emitter region 9. Thus, it is possible to mitigate the influence of a reaction between the gate insulating film 5 and a barrier metal (not shown) disposed between the gate plug 13 and the gate insulating film 5. The influence would otherwise reduce the withstand voltage of the gate due to the increase in the leak current in the gate.

Functions of a semiconductor device 200 according to a comparative example will next be described.

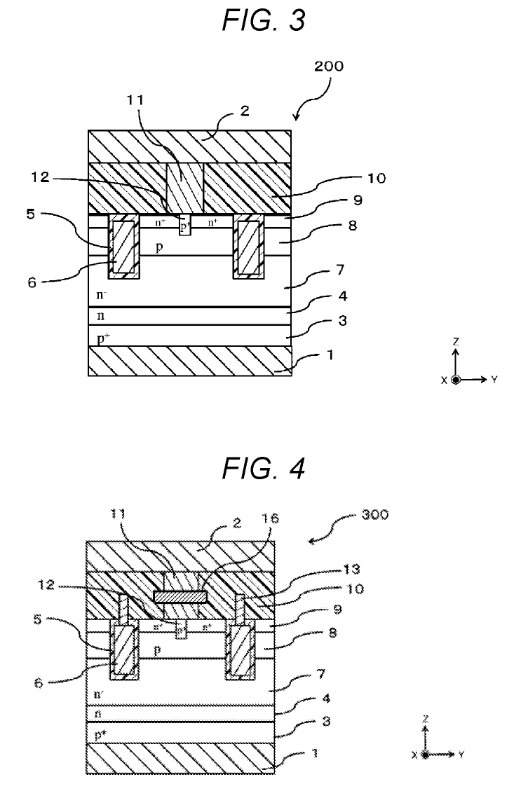

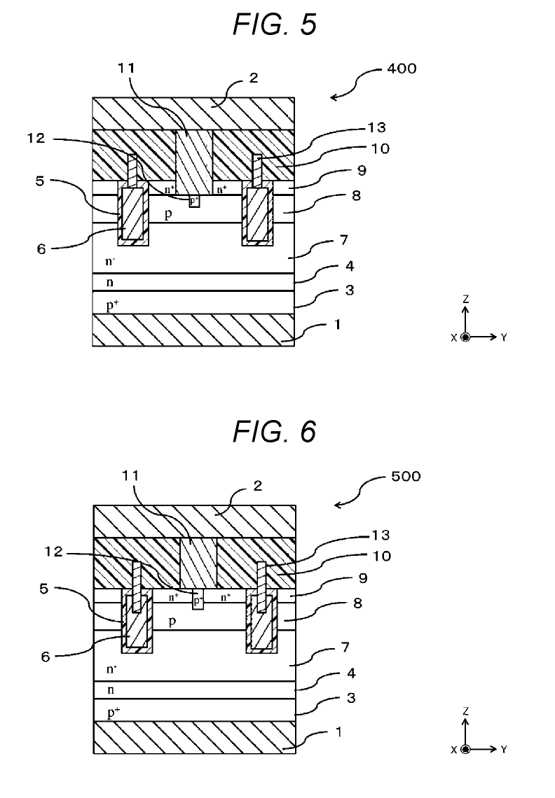

FIG. 3 is a schematic cross-sectional view of the semiconductor device 200 according to the comparative example. The semiconductor device 200 according to the comparative example includes the collector electrode 1, the emitter electrode 2, the p⁺ collector region 3, the n drift region 4, the gate insulating films 5, the gate electrode 6, the n⁻ drift region 7, the p base region 8, the n⁺ emitter region 9, the oxide film 10, the contact plug 11, and the p⁺ contact region 12.

The semiconductor device 200 according to the comparative example has an upper-lower electrode structure similarly to that of the semiconductor device 100 according to the first embodiment. The semiconductor device 200 includes the collector electrode 1 and the emitter electrode 2. The direction from the collector electrode 1 to the emitter electrode 2 is the Z direction.

The semiconductor device 200 according to the comparative example differs from the semiconductor device 100 according to the first embodiment in that the gate plugs 13 are not provided.

In the semiconductor device 200 according to the comparative example, the gate electrodes 6 are not connected to the gate plugs 13, and thus the gate resistance is high and an on/off delay occurs within the device 200 at a time of switching. In addition, this makes the current density non-uniform and the semiconductor device 200 is prone to breakdown.

In contrast, in the semiconductor device 100 according to the first embodiment of the present disclosure, the volume of each gate electrode 6 is increased by providing the gate plug 13 and the resistance is reduced by forming the gate plug 13 from metal. Furthermore, the gate plug 13 is thinner than the gate electrode 6 in the Y direction. Since the facing area where the gate electrode 6 faces the contact plug 11 is increased by the span of the gate plug 13 above the gate oxide 5 in the Z-direction, the gate-emitter capacity Cge increases and the ratio Cgc/Cge falls. It is, therefore, possible to increase the device switching speed.

The function of a semiconductor device 300 according to a second embodiment will next be described.

The semiconductor device 300 according to the second embodiment has an upper-lower electrode structure similarly to that of the semiconductor device 100 according to the first embodiment. The semiconductor device 300 differs from the semiconductor device 100 of the first embodiment in that an intermediate portion 16 is provided in the contact plug 11. The intermediate portion 16 comprises a conductive material, for example, a metal. The width of the contact plug 11 is less than the width of the intermediate portion 16″.

The contact plug 11 of the semiconductor device 300 has a two-layer structure. The intermediate portion 16 is advantageous where misalignment between a first layer and a second layer occurs. Namely, in processing the contact plug 11, it is possible to secure a margin of the misalignment between the lower portion of the contact plug below the intermediate portion 16 and the upper portion of the contact plug above the intermediate portion 16 and thereby further reduce the resistance of the contact plug 11.

Functions of a semiconductor device 400 according to a third embodiment will next be described.

The semiconductor device 400 according to the third embodiment has an upper-lower electrode structure similarly to that of the semiconductor device 100 according to the first embodiment. The semiconductor device 400 differs from the semiconductor device 100 according to the first embodiment in that the contact plug 11 is formed to extend into and through the n⁺ emitter region 9 to directly contact the p-type base region 8.

The semiconductor device 400 improves carrier drawing-out efficiency by forming a portion where the contact plug 11 is formed as a trench contact. It is thereby possible to form a breakdown-resistant device structure.

Functions of a semiconductor device 500 according to a fourth embodiment will next be described.

The semiconductor device 500 according to the fourth embodiment has an upper-lower electrode structure similarly to that of the semiconductor device 100 according to the first embodiment. The semiconductor device 500 differs from the semiconductor device 100 according to the first embodiment in that each gate plug 13 extends into the gate electrode 6.

Increasing the contact area between the polysilicon within the gate electrode 6 and the gate plug 13 can reduce the gate resistance.

While the embodiment and the modified embodiments have been described, the embodiment and the modified embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. A specific configuration of each constituent element included in the embodiments can be selected by a person skilled in the art, as appropriate, from well-known techniques. The accompanying claims and their equivalents are intended to cover such forms or modifications as would fall within the scope and spirit of the inventions.

1. A semiconductor device, comprising:
a first electrode;
a second electrode;
a first semiconductor region of a first conductivity type between the first electrode and the second electrode;
a second semiconductor region of a second conductivity type between the first semiconductor region and the second electrode;
a third semiconductor region of the first conductivity type between the second semiconductor region and the second electrode;
a fourth semiconductor region of the second conductivity type between the third semiconductor region and the second electrode, the fourth semiconductor region comprising at least a first portion and a second portion;
a fifth semiconductor region of the first conductivity type located the first portion and the second portion of the fourth semiconductor region;
a first conductive region extending inwardly of the second, third and fourth semiconductor regions and spaced therefrom by a first insulating region;
a second conductive region extending inwardly of the second, third and fourth semiconductor regions and spaced therefrom by a second insulating region, the first and second conductive regions extending in a first direction within the second, third, and fourth semiconductor regions and spaced from each other in a second direction orthogonal to the first direction;
a third insulating region between the fourth semiconductor region and the second electrode, and between and the first and second conductive regions and the second electrode;
a third conductive region extending from the first conductive region inwardly of the third insulating region; and
a fourth conductive region extending from the second conductive region inwardly of the third insulating region, the third and fourth conductive regions extending in the first direction and spaced from each other in the second direction, wherein widths of the third and fourth conductive regions in the second direction are less than widths of the first and second conductive regions in the second direction, respectively.

2. The semiconductor device of claim 1, further comprising a fifth conductive region extending from the second electrode to the fifth semiconductor region.

3. The semiconductor device of claim 2, wherein the fifth conductive region extends in the first direction, and is spaced from the third and fourth conductive regions in the second direction.

4. The semiconductor device of claim 3, wherein the third insulating region extends between the fifth conductive region and the third conductive region, and between the fifth conductive region and the fourth conductive region.

5. The semiconductor device according to claim 2, wherein the shortest distance from the first electrode to the third conductive region is less than the distance from the first electrode to the fifth conductive region.

6. The semiconductor device of claim 1, wherein the first conductive region and the second conductive region comprise a semiconductor.

7. The semiconductor device of claim 1, wherein the third conductive region and the fourth conductive region comprise a metal.

8. The semiconductor device of claim 1, wherein the fifth semiconductor region extends inwardly of the third semiconductor region.

9. The semiconductor device of claim 1, further comprising a fifth conductive region extending from the second electrode to the fourth semiconductor region.

10. The semiconductor device of claim 1, wherein the third conductive region extends inwardly of the first conductive region.

11. A semiconductor device, comprising:
a first electrode;
a second electrode;
a first semiconductor region of a first conductivity type between the first electrode and the second electrode;
a second semiconductor region of a second conductivity type between the first semiconductor region and the second electrode;
a third semiconductor region of the first conductivity type between the second semiconductor region and the second electrode;
a fourth semiconductor region of the second conductivity type between the third semiconductor region and the second electrode, the fourth semiconductor region comprising a first portion and a second portion;
a fifth semiconductor region of the first conductivity type between the first portion and the second portion of the fourth semiconductor region;
a first conductive region extending inwardly of the second, third and fourth semiconductor regions and spaced therefrom by a first insulating region;
a second conductive region extending inwardly of the second, third and fourth semiconductor regions and spaced therefrom by a second insulating region, the first and second conductive regions extending in a first direction within the second, third and fourth semiconductor regions and spaced from each other in a second direction orthogonal to the first direction;
a third conductive region extending in the first direction and in electrical contact with the first conductive region;
a fourth conductive region extending in the first direction and in electrical contact with the second conductive region; and
a fifth conductive region extending between the fifth semiconductor region and the second electrode, and between the fourth semiconductor region and the second electrode, wherein
the shortest distance between the first electrode and the fifth conductive region is greater than the shortest distance between the first electrode and the third conductive region.

12. The semiconductor device of claim 11, further comprising:
an intermediate portion in the fifth conductive region, wherein
the intermediate portion comprises a metal, and
a width of the fifth conductive region in the second direction is less than a width of the intermediate portion in the second direction.

13. The semiconductor device of claim 11, wherein the fifth conductive region contacts the third semiconductor region.

14. The semiconductor device of claim 11, wherein the third conductive region extends inwardly of the first conductive region.

15. The semiconductor device of claim 11, wherein widths of the third and fourth conductive regions in the second direction are less than widths of the first and second conductive regions in the second direction, respectively.

16. The semiconductor device of claim 11, wherein the second and third conductive regions comprise a semiconductor, and the third and fourth conductive regions comprise a metal.

17. A semiconductor device comprising:
a first electrode, a second electrode, and a plurality of semiconductor regions of different conductivity types interposed therebetween;
a plurality of first insulating layers provided between at least a portion of the plurality of semiconductor regions and the first electrode;
a plurality of third electrodes between the first electrode and the second electrode, at least one of which comprises a first portion and a second portion, wherein the first portion is spaced from an adjacent semiconductor region by one of the plurality of first insulating layers; and
a fourth electrode between the plurality of semiconductor regions and the second electrode and electrically connected to at least one of the plurality of semiconductor regions and the second electrode,
wherein the first portion of the at least one electrode comprises a semiconductor, and the second portion of the at least one electrode comprises a metal.

18. The semiconductor device of claim 17, wherein the first and second portions of the at least one electrode and the fourth electrode, extend in a first direction, and the second portion of the at least one electrode is spaced from the fourth electrode in a second direction orthogonal to the first direction.

19. The semiconductor device of claim 18, wherein the widths in the second direction of the first and second portions of the at least one electrode are different.

20. The semiconductor device of claim 18, further comprising a second insulating layer extending between the second electrode and the plurality of semiconductor regions, wherein the second portion of the at least one electrode extends from the first portion inwardly of the second insulating layer.
